(19) United States
(12) Patent Application Publication
(10) Pub. No.: US 2005/0253571 A1
(43) Pub. Date: Nov. 17, 2005

(54) MEMS waveform generator and adiabatic logic circuits using the same

(75) Inventors: Michael Patrick Frank, Tallahassee, FL (US); Huikai Xie, Gainesville, FL (US)

Correspondence Address: AKERMAN SENTERFITT, P.O. BOX 3188, WEST PALM BEACH, FL, 33402-3188, US

(73) Assignee: UNIVERSITY OF FLORIDA RESEARCH FOUNDATION, INC., Gainesville, FL (US)

(21) Appl. No.: 11/127,926

(22) Filed: May 11, 2005

Related U.S. Application Data
(60) Provisional application No. 60/570,170, filed on May 12, 2004.

(51) Int. Cl. G01R 19/00

(52) U.S. Cl. 324/76.11

(57) ABSTRACT

A micro-electromechanical system (MEMS) waveform generator is provided. The MEMS waveform generator includes a plurality of capacitive sensors. Each of the plurality of capacitive sensors has a movable sensor portion and a corresponding fixed sensor portion. The movable and fixed sensor portions each have a plurality of electrically conductive features. One or more of the electrically conductive features has one or more predetermined non-uniform portions. The MEMS waveform generator further includes an actuator that receives a time-varying input signal and causes each movable sensor portion to move relative to a corresponding fixed sensor portion in response to the time-varying signal. The waveform generator provides a mechanism of synthesizing non-sinusoidal periodic waveforms in an energy-efficient manner. In the context of one exemplary application, the waveform generator provides a mechanism for driving adiabatic logic circuits with extremely low total power dissipation at a given level of performance.

### CROSS-REFERENCE TO RELATED APPLICATIONS

This application claims the benefit of U.S. Provisional Application No. 60/570,170, filed in the United States Patent and Trademark Office on May 12, 2004, the entirety of which is incorporated herein by reference.

### STATEMENT REGARDING FEDERALLY SPONSORED RESEARCH OR DEVELOPMENT

Not applicable.

### FIELD OF THE INVENTION

This invention relates to waveform generators, and, more particularly, to micro-electromechanical system (MEMS) waveform generators for generating AC signals to drive adiabatic circuits.

### BACKGROUND OF THE INVENTION

Conventional non-adiabatic circuit designs are generally thought to be rapidly reaching a limit in terms of power efficiency. Being on the order of approximately one volt, the typical supply voltages for these conventional circuits may already be close to a lower limit. Voltages much lower than this typically lead to poor transistor on-off ratios at room temperature, as well as significant problems with subthreshold conduction and resulting power dissipation owing to leakage. Even if subthreshhold conduction and the resulting leakage can be substantially avoided by, for example, operating far below ambient temperatures, the fundamental thermodynamic limit of approximately eighteen milli-electron volts (i.e., kT 1n(2)≈18 meV) of energy dissipation for an irreversible digital operation (bit erasure) in a room-temperature external environment is probably no more than 30 years away if circuit designs evolve at their current pace. Furthermore, for reliable digital operations, signal energy must remain above approximately 40 kT or 1 eV, a level which should be reached within 20 years. These thermodynamic limits for computing devices and other digital electronic circuitry may be unavoidable without resort to reversible “adiabatic” processes. This is a primary reason that it is expected that a fully-adiabatic and logically-reversible circuit design could, over time, become the norm for many or most high-performance and power-limited computing and communication devices as well as other applications and systems.

In general, adiabatic circuit design encompasses low-power digital design techniques that are based on carrying out a majority of charge transfers across transistors in a gradual or quasi-static fashion in order that the electron “gas” in the circuit always remains at or close to a local equilibrium state. This is done in order to minimize entropy generation and, accordingly, energy dissipation of the overall circuit.

Carrying out charge movements adiabatically in a logic circuit, for example, requires that the circuit's logic gates be driven by AC power supply signals as opposed to DC power signals, and, moreover, that the supply signals have a generally quasi-trapezoidal waveform; that is, the waveforms should exhibit flat-topped wave peaks and flat-bottomed troughs with gradual transitions between the peaks and troughs rather than the steeply transitioning square waves or smoothly curved sinusoidal waveforms of conventional AC circuitry.

The trapezoidal waveforms are generally required in order to ensure that a universal digital logic can be carried out while still obeying the constraints imposed by the need for quasi-static operation. The constraints include that a current never pass through a diode or diode-based transistor, such as a bipolar transistor, that a field-effect transistor (FET) not turn on when there is a voltage across it (V_{DS}≠0), and that the FET not turn off when there is a current through it (I_{DS}≠0).

The advantages of adiabatic circuits can be appreciated by first considering the task of changing the logic value that is stored on a circuit node of capacitance, C, in the context of ordinary voltage-coded logic in which a node transitions through a voltage swing of V=|ΔV|=V_{dd}. If the node is transitioned by connecting it to a constant-voltage power supply at the desired level, energy dissipation of E_{diss}=½CV² is normally unavoidable. By contrast, though, if the node is instead connected to a power supply which is initially at the same voltage level as the original level of the node, but which subsequently ramps to the new level linearly over a time interval t, the energy dissipation is given by:
E_{diss}=s(1+s(e^{-1/s}−1))·CV² (1)
where s=RC/t is the speed fraction, the speed of the ramping event compared with the RC time constant of the circuit, and where R is the effective resistance along the charging path. When t>>RC, Equation (1) approaches E_{diss}=CV²s; that is, the energy savings factor approaches 1/(2s)=t/2RC. Thus, with an adiabatic logic circuit, energy dissipation can be reduced by an arbitrarily large factor as the charging time is increased.

It may seem at first glance that increasing the time for a logic transition is impractical. High performance at low power, not just low power, is typically what is desired. In many situations, though, it is the power dissipation—not the RC time constant of the devices—that limits the maximum switching frequency that is attainable. For example, in a traditional switching event occurring once per cycle at a frequency f, the average power dissipation is given by P_{trad}=½CV²f. Performing the same switching events adiabatically over a ramp time that is ¼ of a full clock cycle, that is t=1/(4f), however, yields an average power of P_{adia}=E_{diss}f=4CV²RCf² since the adiabatic energy dissipation of each switching event is E_{diss}=CV²s=CV²RC/t=4CV²RCf, at one transition per cycle. This clearly is lower than the conventional design, by a factor of 1/(8RCf).

It may well be that an application constrains the switching of individual gates to an average power level of only P_{trad}=P_{adia}=P. The maximum frequencies, f_{trad} and f_{adia}, at which switching power this low can be achieved with an adiabatic circuit versus a traditional one can be estimated as follows. Since P=½CV²f_{trad}, and f_{trad}=2P/CV², while P=4CV²RCf_{adia}², solving for f_{adia} yields:

$${f}_{adia} = \sqrt{\frac{P}{4 {CV}^{2} RC}} = \frac{1}{2 CV} \sqrt{\frac{P}{R}} . \qquad ( 2 )$$

Thus the speedup factor F_{SU}=f_{adia}/f_{trad} that can be gained through adiabatic switching is given by:

$${F}_{su} = \frac{{f}_{adia}}{{f}_{trad}} = \frac{( 1 / 2 CV ) \sqrt{P / R}}{2 P / {CV}^{2}} = \frac{V}{4 \sqrt{PR}} . \qquad ( 3 )$$

Accordingly, given the voltage swing V and charging-path resistance R, the adiabatic speedup increases (by a square-root factor) as the allowed power level P becomes smaller. Since the effective resistance R can be approximated as R≈V/I, where I is the current along the charging path when the total voltage drop along it is V, the speedup factor shown in Equation (3) can be simplified further, yielding the form

$${F}_{su} = \frac{1}{4} \sqrt{IV / P} = \frac{1}{4} \sqrt{{P}_{full} / P} ,$$

where P_{full}=IV is the “full throttle” power dissipation along the charging path when the voltage drop along it is the full logic swing, and P remains defined as the maximum power dissipation that can be tolerated given the application constraints.

Therefore, if, for example, a given conventional design, when operated at the top theoretical speed determined by its electrical characteristics (ignoring power), would dissipate 1,600 times as much power as is actually permissible in a given application, then in principle, an adiabatic version of that circuit could run

$$\frac{1}{4} \sqrt{1 \text{,} 600} = 10$$

times faster than the conventional one under the same power constraint. A long-term advantage of the adiabatic approach to circuit design is that, as devices start running up against energy-dissipation limits while their cost continues to decline, the needed power reduction factors P_{full}/P will likely get larger as the number of devices that can be afforded within a given cost budget increases. It follows, therefore, that the potential speed advantage of adiabatic circuits will increase over time.

Note that the above description did not account for other sources of power dissipation, such as current leakage across nominally turned-off devices. Also, the above description was premised on the assumption that circuit complexity was unchanged by the transition to adiabatic switching.

In a more complete analysis which takes these factors into account, Pₗₖ represents the average leakage power dissipation per logic node, and O_{adia} represents the hardware overhead (blowup) factor of the adiabatic design. The speedup factor in this case turns out to be:

$${F}_{su} = \frac{\sqrt{{P}_{full} ( \frac{P}{{O}_{adia}} - {P}_{lk} )}}{4 ( P - {P}_{lk} )} \qquad ( 4 )$$

which is maximized at the power level P=Pₗₖ(1O_{adia}−1), in which case the speedup is

$${F}_{su} = \frac{1}{4} \sqrt{\frac{{P}_{full} / {P}_{lk}}{{O}_{adia} ( {O}_{adia} - 1 )}} \approx \frac{1}{4} \cdot \frac{\sqrt{{R}_{on / off}}}{{O}_{adia}} \qquad ( 5 )$$

where r_{on/off}=P_{full}/Pₗₖ=Iₒₙ/I_{off} is the on-off current ratio of the device technology, and where the last step in the derivation makes use of the fact that O_{adia}(O_{adia}−1)≈O_{adia}² when O_{adia}>>1.

The on-off ratio itself varies with the device technology. However, it can be as high as r_{on/Off}=e^{V/φ}^{_{T}}, where φ_{T}=kT/q is the thermal voltage (˜26 mV at room temperature T), for the case of surround-gate devices operated in the subthreshhold regime. This yields an adiabatic speedup factor as high as F_{SU}≈e^{V/φ}^{_{T}}/4O_{adia}; this factor is greater than one as long as V>2φ_{T}1n(4O_{adia}). In fact, the potentially large magnitude of these speedups can justify staying at operating voltages that are high enough to keep r_{on/off} large. Note that this only requires small (logarithmic) increase in switching voltages; the energy penalty from the slightly higher voltage can be easily outweighed by the advantages of adiabatic switching. It can be concluded that moving to ever-smaller devices, which require ever-lower voltages, is not always beneficial for maximizing power-performance or even overall cost efficiency of the system.

As demonstrated above, given a fixed constraint on operating power, adiabatic circuits can offer a significant performance advantage over traditional circuits. A cost-performance advantage can also be provided. The raw hardware cost of an adiabatic solution is increased by a factor of O_{adia} as well as by additional factors. But as long as V>4φ_{T} 1n(4O_{adia}) it can be shown that there is still a cost-performance advantage with an adiabatic circuit. The small increase in device size and related cost necessitated by the slightly (logarithmically) higher voltage level is overwhelmed by the larger (exponentially larger) performance gain from energy-efficient adiabatic circuit operation in power-limited scenarios.

An additional consideration for some applications is that the adiabatic overhead factor O_{adia} may actually need to be increased as the power requirements become ever more stringent. The constraint of logical reversibility generally causes the space and time requirements of many known algorithms to increase as the fraction of computational operations that are performed irreversibly are decreased. However, an even more detailed analysis that accounts for this effect reveals that, even when accounting for the increasing overheads, the power-performance and cost-performance of adiabatic logic still beats conventional approaches over time, as the device manufacturing process becomes more cost-efficient and energy increasingly dominates the total cost.

Power supply considerations for adiabatic operations are similarly important. An adiabatic transition transfers an amount of static electrical energy given by Eₜᵣₐₙₛ=½CV² onto or off of a capacitor, while dissipating only E_{diss}=CV²s of this energy to heat, where s=RC/t is the relative switching speed. Therefore the Q (energy-recycling “quality”) factor of this process is Q_{adia}=Eₜᵣₐₙₛ/E_{diss}=1/(2s). The energy transferred comes from, or goes to, some external energy-recovery element, which also has an effective Q factor Qₑₓₜ. Since the total dissipation E_{dtot}=Eₜᵣₐₙₛ(1/Q_{adia}+1/Qₑₓₜ) the overall Q factor is Q=(Q_{adia}⁻¹+Qₑₓₜ⁻¹)⁻¹, that is, it is limited to at most the Qₑₓₜ of the external element. Therefore, achieving all the above predictions requires an external resonant element with a sufficiently high Q factor, or energy-recovery efficiency.

Thus, a very important but heretofore largely overlooked consideration in adiabatic design is that the energy savings provided by an adiabatic design is limited by the energy efficiency of the external element that generates a trapezoidal waveform. Ideally this generator element should be a resonator (i.e., an energy-recovering oscillator) with a high Q factor. Generating an accurate quasi-trapezoidal signal with a conventional electronic resonator, such as using an LC-filter ladder circuit, is difficult, however, since very flat-topped signals (with low ringing amplitudes) require a substantial number of different Fourier components (modes) whose relative frequencies and amplitudes must be precisely tuned. Moreover, if the required inductors and capacitors for the LC oscillator are fabricated on-chip, rather than being discrete components, they generally suffer from a low Q factor (typically only in the tens) due to the low inductance values and high parasitic substrate coupling of the low-coil-count integrated spiral or helical inductors that can be fabricated on-chip using currently available fabrication processes. There is a need to address this issue if the full potential of adiabatic circuits is to be realized.

### SUMMARY OF THE INVENTION

The present invention provides a waveform generator and related method for effectively and efficiently generating substantially trapezoidal and other custom-shaped waveforms. The waveform generator has a high Q factor and small size that allows it to be advantageously used to drive adiabatic circuits in an integrated system. A further aspect of the invention is an adiabatic circuit driven by such a waveform generator.

A waveform generator according to one embodiment of the invention includes a plurality of capacitive sensors. Each capacitive sensor can comprise a movable sensor portion and a corresponding fixed sensor portion. The movable and fixed sensor portions can each have a plurality of electrically conductive features, at least one of which has at least one predetermined non-uniform portion. The waveform generator also can include an actuator for receiving a time-varying input signal and causing the movable sensor portion to move relative to the corresponding fixed sensor portion in response to the signal.

Another embodiment is a MEMS waveform generator comprising an electrostatic actuator as well as a capacitive sensor. The electrostatic actuator can comprise a movable actuator portion and a fixed actuator portion. The movable actuator portion and the fixed actuator portion can each have a plurality of electrically conductive features. With the electrostatic actuator microstructure, a time-varying voltage signal can be applied to the electrostatic actuator so as to cause oscillatory movement of the movable actuator portion. In other embodiments, movement of the movable portion of the MEMS waveform generator can be alternatively effected by electrothermal actuation, electromagnetic actuation, piezoelectric actuation, or even ultrasound actuation.

Still another embodiment is an adiabatic circuit. The adiabatic circuit can include one or more circuit loads and a MEMS waveform generator for driving one or more circuit loads. The MEMS waveform generator can include a plurality of capacitive sensors, each capacitive sensor comprising a movable sensor portion and a corresponding fixed sensor portion. The movable and fixed sensor portions can each have a plurality of electrically conductive features, at least one of the electrically conductive features having at least one predetermined non-uniform portion. The MEMS waveform generator of the adiabatic circuit further can include an actuator for receiving a time-varying input signal and causing the movable sensor portion to move relative to the corresponding fixed sensor portion in an oscillatory manner in response to the signal.

Still another embodiment of the invention is a method of generating a waveform for driving a circuit. The method can include providing a time-varying signal that causes an oscillatory movement of a plurality of movable electrically conductive features, the movable electrically conductive features moving relative to a corresponding plurality of fixed electrically conductive features in response to the time-varying signal. At least one of the plurality of electrically conductive features has at least one predetermined non-uniform portion.

### BRIEF DESCRIPTION OF THE DRAWINGS

A fuller understanding of the present invention and the features and benefits thereof will be accomplished upon review of the following detailed description together with the accompanying drawings, in which:

FIG. 1 is a voltage versus time plot in which an exemplary non-ideal waveform and corresponding nominal (ideal) waveform are superimposed on the same graph.

FIG. 2 is a schematic diagram of a MEMS waveform generator, according to one embodiment of the invention.

FIG. 3 is a schematic diagram of a MEMS waveform generator including an electrostatic actuator, according to another embodiment of the present invention.

FIG. 4 is a schematic diagram providing an expanded view of a capacitive sensor of the MEMS waveform generator illustrated in FIG. 3.

FIG. 5 is a schematic diagram of a circuit including signal sources and the MEMS waveform generator illustrated in FIG. 3.

FIGS. 6(a)-(d) provide top plane views of a MEMS waveform generator according to different embodiments of the invention.

FIG. 7 is a timing diagram illustrating the nominal clock/power supply rail signals for a fully adiabatic logic family referred to as 2LAL driven by a MEMS waveform generator according to another embodiment of the invention.

FIGS. 8(a)-(h) illustrate various 2LAL logic circuit gates that can comprise an adiabatic circuit according to still another embodiment of the invention.

FIG. 9 is a plot of a simulated output waveform from a MEMS waveform generator according to the invention.

FIG. 10 is a perspective view of a complete MEMS waveform generator according to the invention.

FIG. 11 is a plot of simulation results obtained for an exemplary adiabatic circuit driven by a MEMS waveform generator according to the invention versus a conventional circuit.

### DETAILED DESCRIPTION

One aspect of the invention is a MEMS resonator or waveform generator that operates as a displacement-controlled varactor in generating a desired waveform. When placed in series with a DC voltage source and a circuit load, the MEMS waveform generator acts as a variable voltage divider that presents a time-varying voltage signal to the load. According to one of the particular embodiments described herein, this voltage signal increases and decreases as energy is transferred back and forth between the mechanical (kinetic) and electrostatic (potential) domains of the system. Accordingly, when driven at or near its natural resonant frequency, the MEMS waveform generator can efficiently generate diverse custom-shaped waveforms, including resonant energy-recovering AC voltage waveforms. In general, the MEMS waveform generator can generate various AC waveforms such as a substantially trapezoidal waveform or triangular waveform.

A substantially trapezoidal or a quasi-trapezoidal waveform is defined herein as a waveform having flat, or nearly flat, wave peaks and wave troughs coupled with gradual transitions between the flat-topped peaks and flat-bottomed troughs. Such a waveform can be more formally characterized by two conditions.

The first condition is a small fractional voltage variation, ν_{V}=ΔVᵥₐᵣ/ΔVₘₐₓ, where ΔVᵥₐᵣ is the maximum absolute range of voltage variation around the nominal constant level within the span of a single wave peak or trough, and ΔVₘₐₓ is the nominal voltage difference between the wave peak and trough. An example of a “small” value for the fractional voltage variation ν_{V} would be approximately 0.01 or smaller.

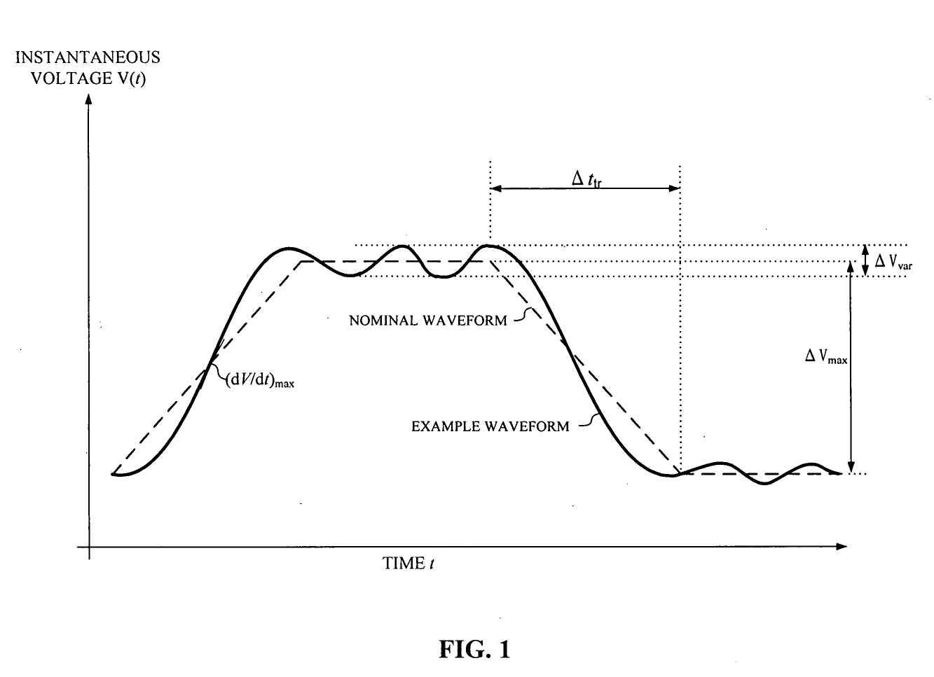

The second condition that characterizes a substantially trapezoidal waveform is a small maximum relative transition slope, sₘₐₓ=(dV/dt)ₘₐₓ/(ΔVₘₐₓ/Δtₜᵣ), where V=V(t) is the instantaneous voltage, t is real time, and Δtₜᵣ is the transition or ramp time. A “small” value for the parameter sₘₐₓ would be a value close to 1, for example, 1.01 or smaller. In the case of the two-level adiabatic logic (2LAL) family, for example, the ideal transition or ramp time is ¼ of the clock period f, Δtₜᵣ=¼f. Substantially trapezoidal waveforms are well suited for driving adiabatic circuits. The various parameters of the above characterization are illustrated in FIG. 1, wherein an exemplary waveform and corresponding normal waveform are superimposed on a common graph that plots voltage versus time.

As will be readily apparent from the ensuing description, other custom-shaped waveforms in addition to substantially trapezoidal and triangular waveforms also can be efficiently generated with the MEMS waveform generator described herein. These custom-shaped waveforms can be advantageously utilized in a variety of contexts, such as in baseband and ultra-wideband (or pulse-based) signaling schemes for RF communication.

As explained herein, different custom-shaped AC waveform tailored to diverse signaling and processing needs can be achieved by adjusting the geometry of the MEMS waveform generator. The design specification of the geometry of the MEMS waveform generator, as described below, can determine a capacitance response curve corresponding to a particular shape of the generated output-voltage waveform. Conversely, a profile for generating a desired wave shape can be straightforwardly approximated by differentiating the response curve.

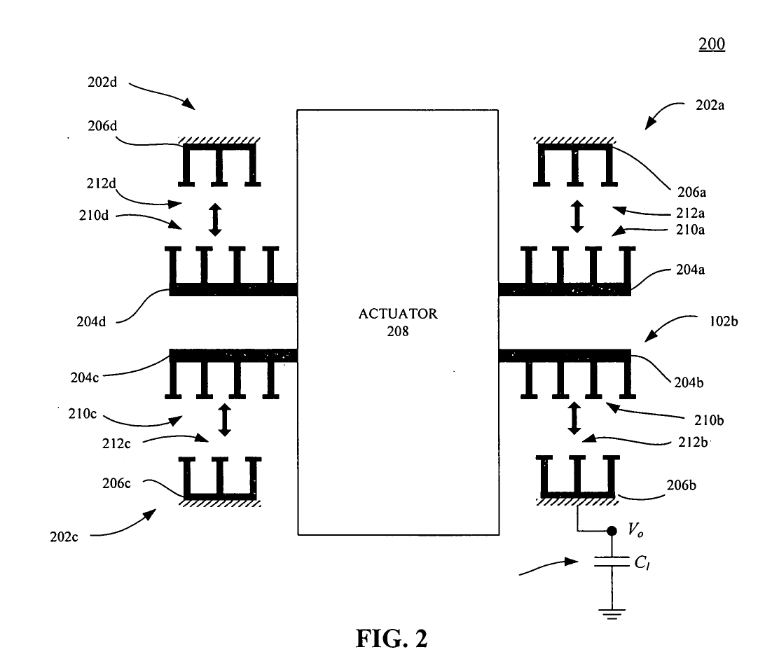

FIG. 2 provides a schematic diagram of a MEMS waveform generator 200 for generating waveforms, according to one embodiment of the invention. The MEMS waveform generator 200 illustratively comprises a plurality of capacitive sensors 202a-d. Each capacitive sensor 202a-d illustratively comprises a movable sensor portion 204a-d and a corresponding fixed sensor portion 206a-d. The MEMS waveform generator 200 also illustratively includes an actuator 208 for moving each of the movable sensor portions 204a-d relative to a corresponding one of the fixed sensor portions 206a-d in response to a time-varying signal received by the actuator 208. The MEMS waveform generator 200 can be disposed on a single chip (not shown) with the fixed sensor portions 206a-d embedded in or otherwise anchored to the chip. The movements of each movable sensor portion 204a-d relative to a corresponding fixed sensor portion 206a-d are indicated by the bi-directional arrows. As explained below, the movement of each movable sensor portion 204a-d is an oscillatory movement.

The movable sensor portions 204a-d comprise a plurality of electrically conductive features 210a-d. Similarly, the fixed sensor portions 206a-d each comprise a plurality of electrically conductive features 212a-d. The electrically conductive features 210a-d, 212a-d illustratively comprise comb fingers. When the actuator has moved a movable sensor portion 204a-d to the maximum extend toward a corresponding fixed sensor portion 206a-d, the respective fingers of each of the two sensor portions are interdigitated with one another.

Each comb finger illustratively has a non-uniform portion in the form of a rectangular-shaped end portion that is enlarged relative to the rest of the comb finger. In different embodiments, the electrically conductive features 210a-d, 212a-d comprise different shapes and have different non-uniformities. Examples of other non-uniformities include triangular-shaped end portions and non-linear surface portions. As explained below, the nature of the particular non-uniformity is dictated by the type of waveform that is to be generated.

Moreover, in some other embodiments, the electrically conductive features 210a-d, 212a-d do not have shapes that are identical to one another. In some embodiments, not every one of the electrically conductive features has even a single non-uniform portion. In each embodiment, though, each capacitive sensor has at least one non-uniform feature.

This non-uniformity is a key aspect of the MEMS waveform generator 200. The particular waveform generated by the MEMS waveform generator 200 is a function of the specific geometry of the electrically conductive features 210a-d, 212a-d and, in particular, the nature of the non-uniformity of a portion or portions of each feature. More particularly, as a result of the non-uniformity of the features, the capacitances associated with the capacitive sensors 202a-d as each of their respective movable sensor portions 204a-d moves relative to a corresponding one of the fixed sensor portions 206a-d changes nonlinearly. That is, non-uniformity in the electrically conductive features results in a nonlinear capacitance-versus-displacement response curve as a movable sensor portion 204a-d moves relative to a corresponding fixed sensor portion 206a-d.

Thus, the MEMS waveform generator 200 can generate, for example, a non-sinusoidal waveform in response to a sinusoidal signal applied to the actuator 208. This can be particularly advantageous in the context of adiabatic circuits, especially adiabatic logic circuits. Effecting charge movement adiabatically in a logic circuit typically requires that the logic gates of the circuit be driven with AC power supply signals—as opposed to the DC power supply signals typically utilized in conventional logic circuits—and that the waveform of the signal be quasi-trapezoidal or substantially trapezoidal. As already noted, a waveform that is ideal for driving adiabatic circuits is characterized by a flat-topped peak and flat-bottomed trough. A waveform having a flat-topped peak can be generated if the MEMS waveform generator 200 is configured such that at least part of the movable sensor portion 204a-d that is separated by a small gap from the fixed sensor portion 206a-d overlaps the fixed sensor portion for 25 percent or more of a cycle period of the circuit. As described in the Examples section, below, the necessary feature geometry needed to effect this result as well as to generate different substantially trapezoidal and quasi-trapezoidal waveforms can be determined using available simulation tools. (See Examples, below.)

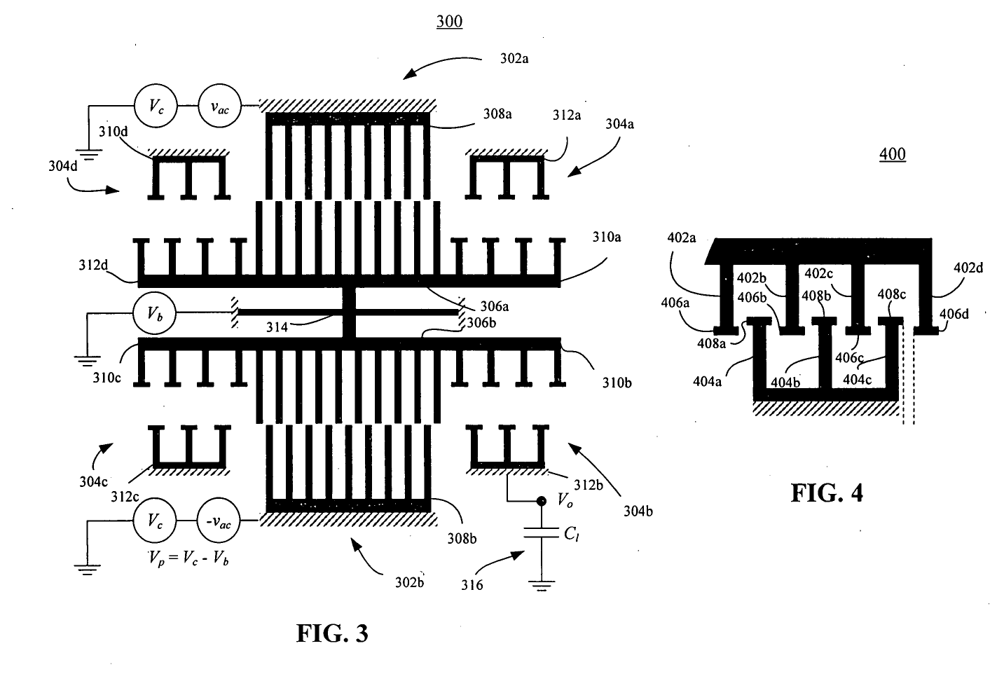

According to different embodiments, different types of signal-responsive actuators can be used for moving a movable sensor portions relative to a corresponding one of the fixed sensor portions of a capacitive sensor. The actuator in one such embodiment is a magnetic-based actuator. In another embodiment, the actuator alternatively is a thermal-based actuator. The actuator according to still another embodiment is a fluid-based actuator. The actuator can be a piezoelectric actuator according to yet another embodiment. In still another embodiment, the actuation can be accomplished using ultrasound. FIG. 3 illustrates yet another actuator for a particular embodiment of a MEMS waveform generator 300 in which the actuator is an electrostatic actuator.

As illustrated, the MEMS waveform generator 300 comprises an electrostatic actuator having capacitive actuator portions 302a, 302b. The MEMS waveform generator 300 additionally includes a plurality of capacitive sensors 304a-d that define a sensor structure. The actuator and sensor structures can each comprise microstructures that when integrated with one another on a substrate or chip define an integrated microstructure. The operative size of each such microstructure is in the range of approximately 100 μm by approximately 60 μm.

Each of the capacitive actuator portions 302a, 302b of the actuator structure includes a movable electrically conductive portion 306a, 306b and a fixed electrically conductive portion 308a, 308b. Similarly, each of the capacitive sensors 304a-d of the sensing structure comprises a movable portion 310a-d and a fixed portion 312a-d.

Additionally, the resonator MEMS waveform generator illustratively includes a flexural beam 314, such as a spring beam, to which each of the movable electrically conductive portions 306a, 306b of the actuator structure is connected. Each of the movable portions 310a-d of the sensing structure also connect to the flexural beam 314. The flexural beam 314 in turn can fixedly connect to a substrate or chip (not shown), to which the movable electrically conductive portions 306a, 306b of the respective capacitive actuator portions 302a, 302b of the actuator structure and the movable portions 310a-d of the respective capacitive sensors 304a-d of the sensing structure also connect.

As schematically illustrated, each movable electrically conductive portion 306a, 306b and each fixed conductive portion 308a, 308b comprises a plurality of electrically conductive features, which are illustratively spaced-apart extensions or comb fingers. Each of the movable electrically conductive portions 306a, 306b moves relative to a corresponding one of the fixed electrically conductive portions 308a, 308b such that the plurality of electrically conductive features of the respective portions are interdigitated with one another when each movable electrically conductive portion is sufficiently close to a corresponding one of the fixed electrically conductive portions.

Likewise, with respect to each of the capacitive sensors 304a-d of the sensing structure, each movable portion 310a-d and each fixed portion 312a-d comprises a plurality of electrically conductive features, which also are illustratively spaced-part extensions or comb fingers. Each movable portion 310a-d moves relative to a corresponding one of the fixed portions 312a-d such that, when each movable portion is sufficiently close to a corresponding fixed portion, their respective electrically conductive features are interdigitated with one another.

Referring additionally now to FIG. 4, each of the movable and fixed electrically conductive features of an exemplary capacitive sensor 400 comprises a non-uniform portion 406a-d, 408a-c at the tip of the feature 402a-d, 404a-c. Thus, as explicitly illustrated, each electrically conductive feature is in the shape of a comb finger having a capped, or rectangular, end 406a-c, 408a-c that is enlarged relative to the remainder of the comb finger. In general, a non-uniform portion is a portion other than uniform plane-surfaced feature. One or more of the features can alternatively comprise other non-uniform portions, as described above. Uniform, as used herein, denotes a straight rectangular beam or uniformly planar surface. Accordingly, a curved beam or beam with multiple, discrete portions that have different cross-sectional areas or shapes is a non-uniform structure.

The movable portions of the actuator and sense microstructure are physically anchored to the substrate through the flexural beam 314. The flexural beam 314 is free to vibrate in the plane of the chip bounded by a maximum amplitude position generally symmetric about the rest position of the spring beam. As the flexural beam 314 moves back and forth in response to an oscillatory excitation signal applied to the actuator portions 302a, 302b the capacitance of the capacitive sensors 304a-d changes as a result. Similarly, the excitation applied to one actuator portion 302a is illustratively provided by the AC and DC voltage sources connected in series to the actuator portion. The excitation applied to the other actuator portion 302b is illustratively provided by separate AC and DC voltage sources connected in series to the other actuator portion. FIG. 4 shows the position of the exemplary sensor 400 when the flexural beam 314 is at a maximum displacement position.

A circuit 316, which illustratively comprises a capacitor having capacitance C₁, is illustratively driven by the MEMS waveform generator 300, the circuit 316 being shown connected to the capacitive sensor 304b, which has a time-varying output voltage V₀. According to another embodiment, however, one or more of the other capacitive sensors 304a, 304c, 304d can also connect to the circuit 316. Through various combinations of connections with the capacitive sensors 304a-d, frequency and/or amplitude doubling can be obtained as described more particularly below.

By connecting each of the capacitive sensors 304a-d directly to the load of the circuit, an effective doubling of frequency is attained. Each time the movable structure of the MEMS waveform generator 300 makes 1 complete cycle, this leads to an overlap of the comb fingers of the capacitive sensors 304b, 304c on one side, and subsequently overlap of the comb fingers of the capacitive sensors 304a, 304d on the other side. Accordingly, the waveform generated by the MEMS waveform generator acts as a resonator making 2 cycles in the time for one displacement cycle.

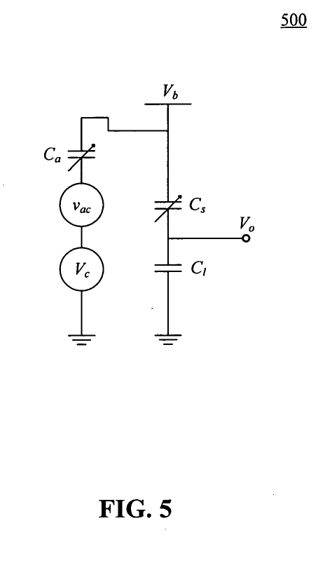

The electrical behavior of the MEMS waveform generator 300 can be described in terms of the circuit 500 schematically illustrated in FIG. 5. In the circuit 500, the capacitance for the actuator structure is denoted Cₐ, that for the sensor structure is denoted Cₛ, and lastly, the capacitance of the load is denoted C₁. The actuator structure and capacitive sensors are schematically represented in the circuit as variable capacitors. Changes to Cₐ and Cₛ result in changes to the voltage across the load C₁, which is driven by the MEMS waveform generator 300.

During normal operation of the circuit 500, a DC bias voltage V_{b} is applied to the movable comb fingers of both actuation and sensing structures, while an optional DC voltage plus an AC voltage signal (V_{c}+ν_{ac}) is applied to the stationary comb fingers of the actuator structure.

The electrostatic force generated by the features of the actuator structure is:

$$\begin{matrix}{F}_{e} = \frac{1}{2} \frac{\partial {C}_{a}}{\partial x} {( {V}_{p} + {V}_{ac} cos ω t )}^{2} \\ = \frac{1}{2} \frac{\partial {C}_{a}}{\partial x} ( {V}_{p}^{2} + \frac{{V}_{ac}^{2}}{2} + 2 {V}_{p} {V}_{ac} cos ω t + \frac{{V}_{ac}^{2}}{2} cos 2 ω t ) ,\end{matrix} \qquad ( 6 )$$

where Vₚ=V_{c}−V_{b}. In order to suppress the second harmonic term, Vₚ is preferably set much greater than V_{ac}. When operating at resonant frequency, the vibration amplitude of the fundamental frequency term will be multiplied by a factor of Q and will be the dominant term for the force. The maximum applied voltage which can be used is limited by the oxide and air breakdown voltages. If the MEMS waveform generator has a sufficiently small air gap (˜0.1 μm; denoted by dₛ), then air breakdown will generally be the dominant voltage limiter. The air breakdown voltage is approximately 110 V per one μm of air gap. Accordingly, the maximum applied voltage is about 10V. Simulations performed have indicated that sufficient displacement can be achieved at Vₚ=10V. The output voltage V₀ can be much smaller than 10V, depending on the load capacitance, and will be tuned to the transistor operating voltage. Due to the high impedance output node, a buffer or operational amplifier can be used to drive a bonding pad for testing purposes.

The movement of the flexural beam 314 can be modeled by a sinusoidal function, or more generally, by an arbitrary-shaped periodic AC excitation driving signal ν_{ac} presented at the fixed electrically conductive portions 308a, 308b of the actuator structure, with a frequency at or near the structure's resonant frequency. The natural resonant frequency of the structure is given by ωᵣ=(k/m)^{1/2}, where k and m are respectively the spring constant and mass of the resonator. The drive frequency is preferably within the 3-dB bandwidth, i.e., |ω−ωᵣ|<ωᵣ/Q, where Q is the quality factor of the resonator and is assumed to be much greater than 1. The resultant AC electrostatic force resonantly “pumps up” the amplitude of the oscillations of the movable portions of the MEMS waveform generator 300. The mode of motion of the resonator is that the central region of the flexural beam 314 flexes back and forth in response to the oscillating changes in force. The movable portions of the actuator and sensor structures comprising electrically conductive features on either side of the flexural beam 314 are anchored to a center point along the flexure and thus also move in the same direction as the flexure.

Output signals are generated by each of the illustrated capacitive sensors 304a-d. The two capacitive sensors on one side 304a, 304d are in phase with one another, and the two capacitive sensors on the opposing side 304b, 304c are in phase with one another. The former pair of capacitors 304a, 304d are 180 degrees out of phase with the later pair of capacitive sensors 304b, 304c. Thus, the former pair of capacitive sensors 304a, 304d, and the later pair of capacitive sensors 304b, 304c can be utilized differentially to double the amplitudes of the output signals. Alternatively, each capacitive sensor 304a, 304d on one side can be electrically tied with a corresponding one 304b, 304c so as to double the frequencies of the output signals, as noted above. In yet another embodiment, all four capacitive sensors 304a-d can be tied together electrically so as to double both the frequency and the amplitude of the output signal provided by the waveform generator 300.

As described already, each of the electrically conducive features of the capacitive sensors 304a-d has non-uniform portion, the non-uniformity of each feature illustratively being a rectangular end portion that is enlarged relative to the remaining portion. As also described already, the electrically conductive features can alternately comprise other non-uniformities such as a triangular-shaped end portion, an end portion of a trapezoidal shape, a surface portion that is curved, or a portion with a non-uniform vertical depth (perpendicular to the substrate). The desired non-linearity of the output of the MEMS waveform generator 300 is obtained by tailoring the particular shape of the electrically conducive features of the capacitive sensors 304a-d. Since a resonator, in general, begins to exhibit sinusoidal mechanical vibrations whenever it reaches resonance, the particular shaping of the features effects desired custom waveforms that can be generated by the MEMS waveform generator in response to sinusoidal mechanical vibrations while operating at a high Q.

With regard to the specific shape of the electrically conductive features in the form of comb fingers with enlarged rectangular end portions, it should be noted that the sides of the features, which normally carry most of the electrical field, overlap the walls of the surrounding finger edges when interdigitated as the movable portions reach extend to the maximum amplitude position. In this position the interdigitated features are separated by a relatively narrow gap. The narrow gap accordingly induces a larger sensing capacitance in the capacitive sensors 304a-d. The non-uniform shape of the features are such that the capacitance of the sensors 304a-d changes in a non-linear fashion with respect to the displacement of the flexural beam 314. This unconventional, non-uniform shape for a comb finger geometry of the features thus creates a non-sinusoidal waveform when the flexural beam 314 oscillates sinusoidally.

The result is in stark contrast to that of a conventional MEMS resonator. An objective using a conventional MEMS resonator is to minimize the non-linearity of the output so as to obtain a waveform as close as possible to an ideal sine wave. In practice, a roughly sinusoidal waveform is generated when a resonator beam of the conventional MEMS resonator oscillates sinusoidally. The desired sinusoidal wave shape is produced by the partial overlap of straight linear plates or fingers of the conventional MEMS resonator wherein the capacitance changes linearly with oscillating displacements of the flexural beam.

A MEMS waveform generator according to the invention can be made of various materials including polysilicon or single-crystal silicon depending on the available microfabrication technology. In a preferred embodiment, electrically conductive features are formed from single crystal silicon or other pure-crystalline materials. In the future, though, it may be desirable to utilize materials having greater stiffness, such as diamond. Such materials may ultimately be preferred once the associated processing technologies mature.

MEMS technology is preferably utilized to fabricate to a MEMS waveform generator according to the invention because this technology permits the waveform generator to be made relatively small, in the range of approximately 100 μm by approximately 50 μm, enabling it to exhibit a high Q factor, and to be operable at high frequencies up through the GHz range. Several fabrication processes already exist that can produce MEMS elements integrated with CMOS electronics on the same chip. A MEMS resonator according to one embodiment of the invention can be formed using CMOS-MEMS processes and can provide a high-Q of 1,000 or more, at frequencies in the microwave (GHz) range. Alternatively, lower-frequency (1-100 MHz range) high-Q waveform generators or resonators can also be provided by the invention for ultra-low-power, low-frequency applications, for which adiabatic circuits are particularly well suited. The invention can thus replace low Q conventional LC based electronic oscillators and can provide improved circuit performance at low power for a variety of circuit types.

The sinusoidal waveform that would normally be produced by a DC voltage applied to an oscillating MEMS structure can be remapped into a trapezoidal format by tailoring the shape-profile of the structures (e.g., comb fingers) that are used for electromechanical transduction. High Q can be achieved by reducing gas and structural damping using vacuum packaging and low-loss materials such as single-crystal silicon.

As noted above, a MEMS waveform generator according to the invention is preferably fabricated using single-crystal silicon and is preferably fabricated to be CMOS-compatible. CMOS compatibility enables the formation of the MEMS waveform generator or resonator on a single chip that includes various analog and/or digital electronic circuits.

Major figures of merit (quantities to maximize) for resonators according to the invention include:
1. Effective quality factor for transitions Q_{eff}=Eₜᵣ/E_{diss}, where Eₜᵣ is the energy transferred to or from the load on each transition, and E_{diss} is the energy dissipated in the resonator per clock cycle.
2. Area-efficiency ηₑₐ=Eₜᵣ/A, where A is the resonator area and Eₜᵣ is the energy transferred. This determines the inverse ratio between the area consumed by the resonator and that consumed by the logic, which contributes to the cost overhead of the adiabatic solution.

Major figures of demerit (quantities to minimize) for the resonator design include:
1. Maximum transition slope sₘₐₓ=(dC/dt)ₘₐₓ÷(ACₘₐₓ/Δtₜᵣ), where C is the instantaneous sense-structure capacitance, t is real time, ΔCₘₐₓ is the total capacitance swing needed to obtain the desired voltage variation, and Δtₜᵣ=¼f is the transition time, ¼ of the clock period in the case of two-level adiabatic logic (2LAL) circuits as described below. Ideally the entire capacitance swing should occur at a constant rate, in which case sₘₐₓ=1, but a non-ideal waveform might have a steeper slope than this in some places. The sₘₐₓ value permits derivation of an upper bound on the total energy dissipation of the logic transition, as a multiple of that for the ideal (sₘₐₓ=1) case.
2. Fractional capacitance variation ν_{C}=ΔCᵥₐᵣ/ΔCₘₐₓ, where ΔCᵥₐᵣ is the maximum range of sense-structure capacitance during the ¼ of a cycle during which the capacitance (and output voltage) is supposed to remain constant. This can be used to provide an upper bound on the maximum voltage mismatch ΔV that may occur whenever two circuit nodes are connected that are nominally supposed to be at equal logic levels; this mismatch leads to a ½C(ΔV)² dissipation that would not occur in the ideal case.

Finally, the resonant frequency f of a MEMS waveform generator according to the invention should not itself necessarily be minimized or maximized, but rather should be chosen so as to maximize the overall power-performance (or cost-performance) of the overall design, that is, taking into account the MEMS waveform generator as well as the other circuit parameters.

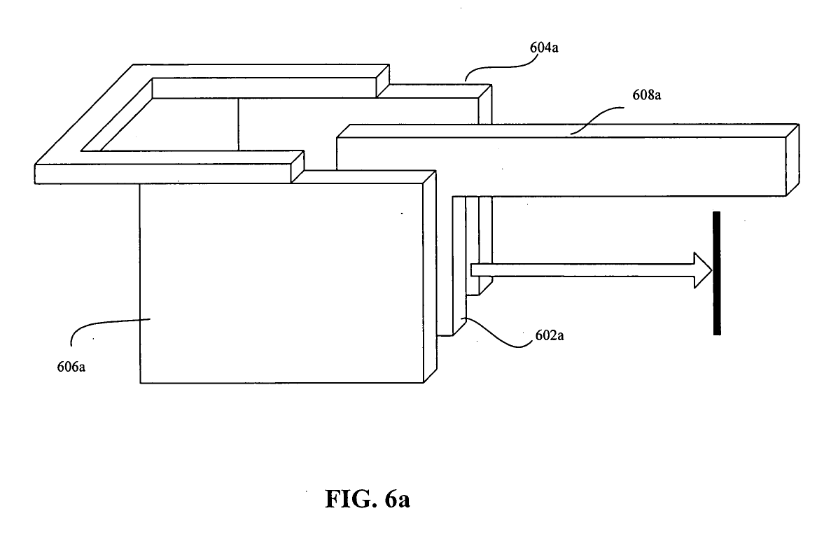

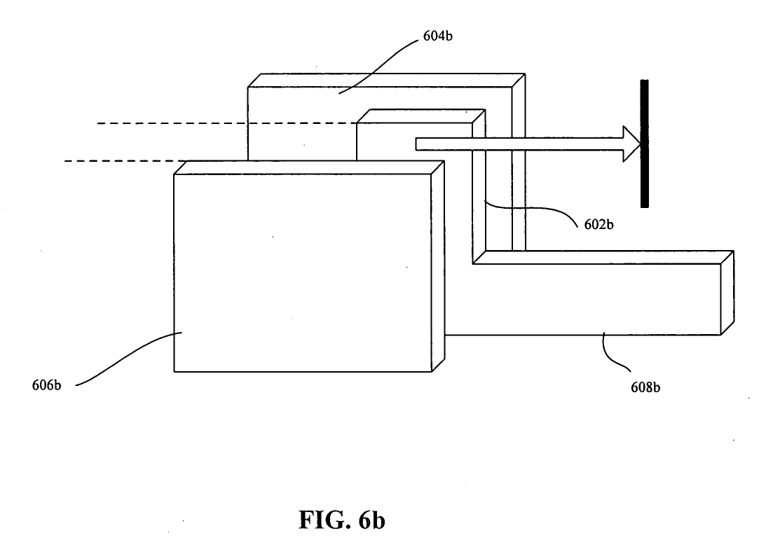

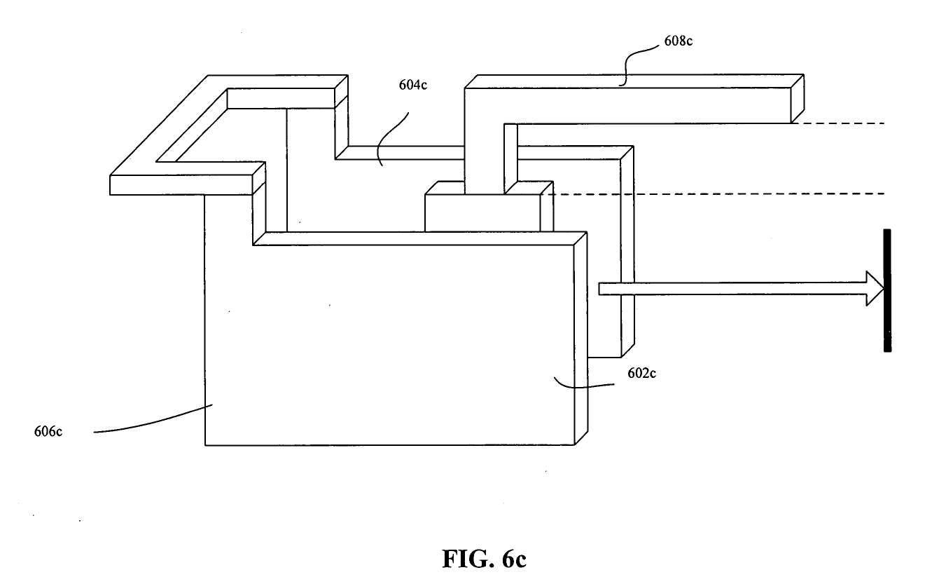

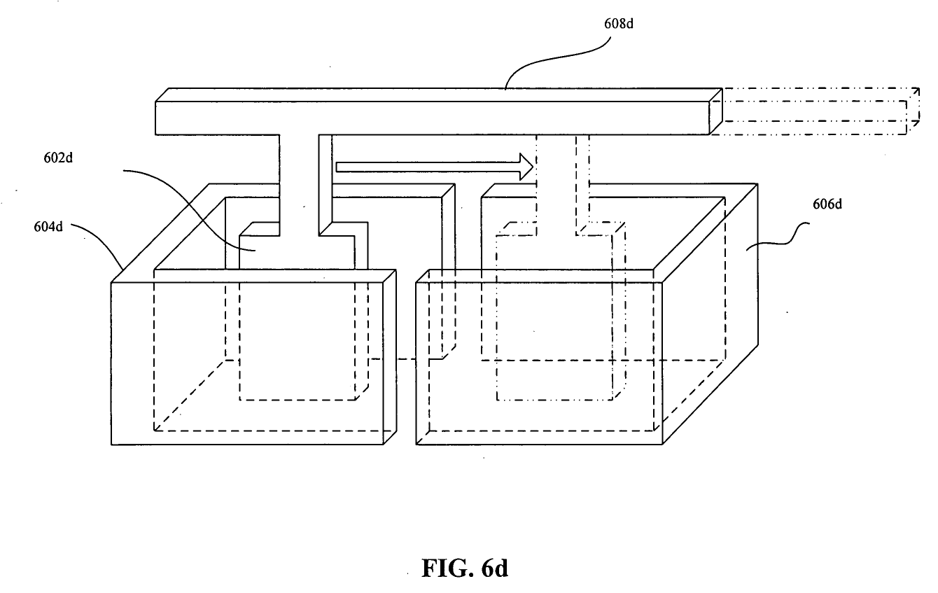

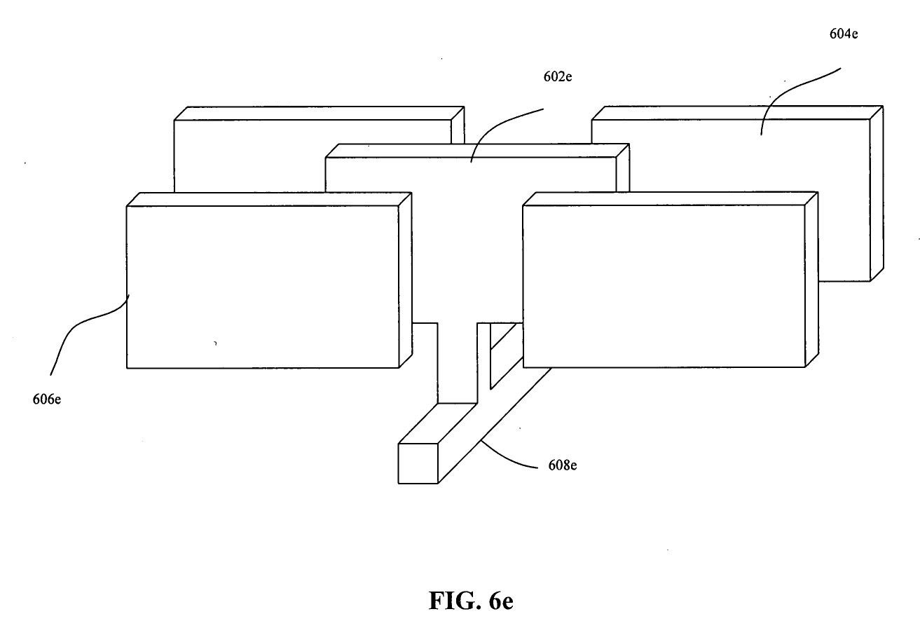

FIGS. 6(a)-(e) show details of additional exemplary MEMS waveform generators comprising alternative non-uniform comb finger shapes 602a-e surrounded by a pair of fixed plates 604a-e, 606a-e, according to various other embodiments of the invention. In each of these alternate embodiments, the entire movable plate is overlapping the fixed plate structure, except for (in the case of FIGS. 6c-e) a portion which extends up (or down) vertically to an overhead mechanical support arm 608a-e. These embodiments increase the magnitude of the capacitance variation while reducing the magnitude of departures from the trapezoidal wave shape desired for adiabatic circuits. In addition, these designs maximize the vertical (z) thickness for maximum overlap capacitance per planar area, and minimize the gap size for maximum overlap capacitance per-area.

The shape of the capacitance-versus-position response curve, and the output voltage waveform, can be fully tailored in these designs by adjusting the height profile of the fixed and/or movable plates. Optimized shape tailoring requires solving a complex inverse problem. One way to approximately solve this problem involves differentiating the desired capacitance-position response curve to obtain the thickness (z) profile of a movable plate that will produce approximately the desired response curve (neglecting fringing capacitances) as it crosses the edge of a larger stationary plate. An initial design obtained in this fashion can then be fine-tuned by hand or automatically with the assistance of electrostatic solvers to yield a near-exact match to the desired shape.

Based on the design and analysis work already performed, MEMS waveform generators or resonators according to the invention will provide an effective Q factor as high as 100 or more, using an area not much greater than that of the logic circuit being driven. The resonator Q can be increased further by systematically identifying and eliminating the major sources of power dissipation. Leakage losses in the logic circuitry can be reduced exponentially by slight (relatively logarithmic) up-scaling of the operating voltage and device size. In the long run, the cost of these small increases are more than outweighed by the power-performance advantages of the adiabatic approach, given improvements in manufacturing efficiency. Circuit size will not be a limiting concern in the near future with the introduction of 3-D integration techniques, made feasible by the ultra-low power dissipation of the adiabatic designs.

In this application, the adiabatic logic design style 2LAL described above that was developed by one of the Inventors is utilized herein to aid in describing the invention. MEMS resonators according to the invention are well suited for resonantly generating (with high Q, such as >100) the 4-tick (4 transition-time) trapezoidal waveforms needed to drive the 2LAL circuits. Although well suited for this purpose, the invention is in no way limited to application to adiabatic circuits.

As per its name, 2LAL uses two distinct voltage levels (high and low), analogous to conventional CMOS, but unlike some earlier adiabatic logic styles such as SCRL (Split-Level Charge Recovery Logic). Nevertheless, 2LAL retains some desirable properties of SCRL, such as being fully adiabatic and permitting pipelined sequential circuits. Further, 2LAL fixes a bug causing non-adiabatic dissipation that was present in the original version of SCRL. 2LAL also has some particularly desirable other properties including:
1. Short cycle time: only 4 adiabatic transition times (4 ticks) per complete clock period.
2. Low latency: only 1 tick of latency per logic level/pipeline stage.
3. Low number of supply rails: only 4 distinct driving signals need be supplied.

The first of these properties implies a low initiation interval (thus high throughput) for pipelines and sequential logic built from 2LAL gates. Also, transitions take place over an entire ¼ of the clock cycle, which is the maximum possible in fully-adiabatic logic. This minimizes the energy dissipation for transitions occurring at a given clock frequency. It also minimizes the slope of the transitions, which makes it easier to obtain the desired slope in the resonant power supply (see next section), and minimizes the duty cycle (active high time/cycle time), which makes it easier for the power supply to keep the high/low signal levels constant. In essence, a cycle time of 4 ticks requires a trapezoidal driving signal that is as close as possible in shape to a sine wave, and thus is easiest for a resonator to generate with high Q (since the energy in the higher-order harmonics is lower).

The second property, of only 1 transition time or “tick” of latency per logic level guarantees the minimum possible time for information to propagate down a logic pipeline, given the transition time, and thus minimizes stalling for data-dependent operations.

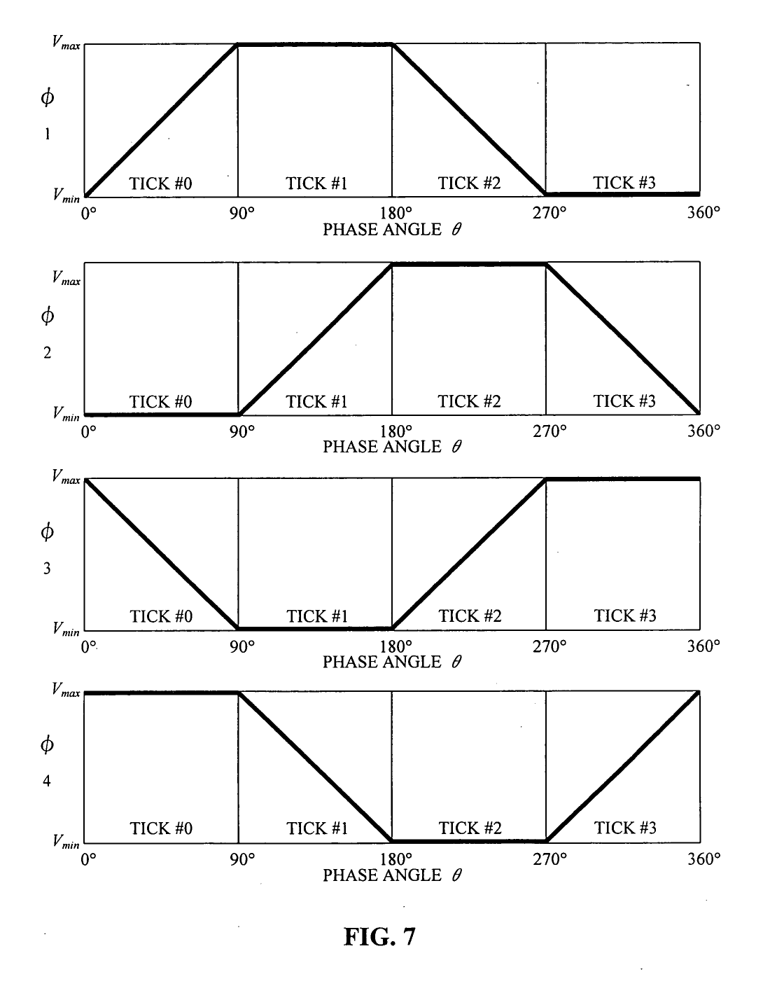

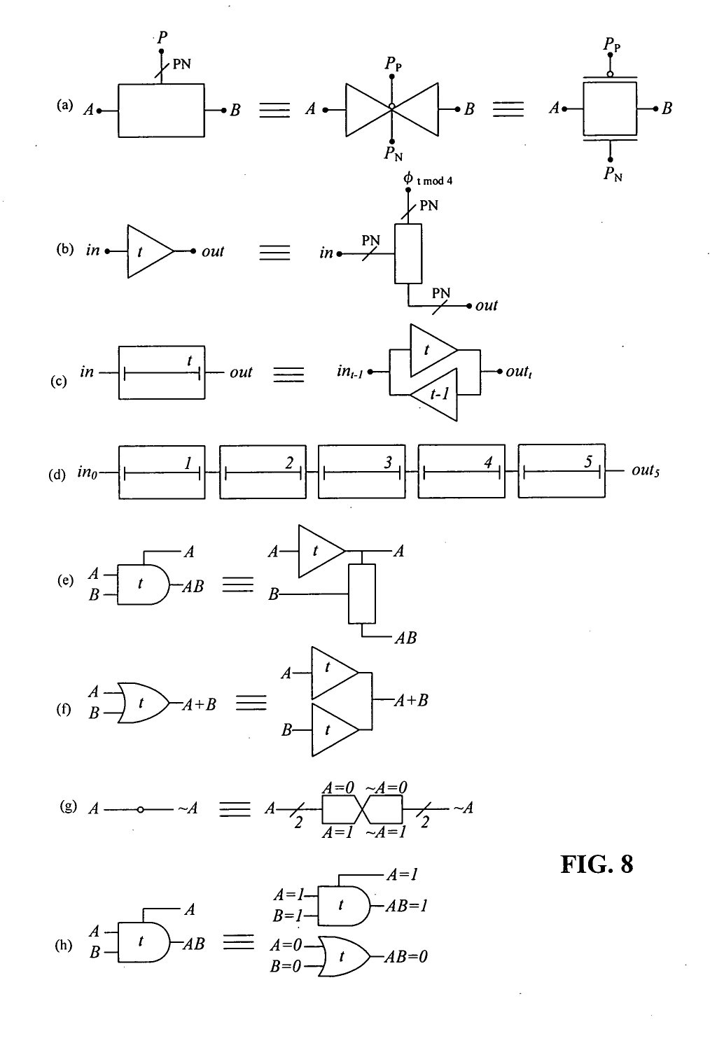

The third property, low number of supply rails, minimizes the area required for implementing the resonators, since as few as possible of them are needed. At least 4 supply signals are needed for fully-adiabatic logic. FIG. 7 shows the rail signals needed for driving a 2LAL logic circuit. Some of the basic elements of 2LAL logic circuits are illustrated in FIG. 8.

Current designs have been implemented using Cadence for these and other basic 2LAL cells, as well as higher-level blocks such as single-bit and multi-bit adders and multipliers. Development of fully-adiabatic DRAM and SRAM cells is also ongoing. Using the invention, a complete suite of practical fully-adiabatic building blocks can be built, suitable for constructing microprocessors, DSPs, and ASICs. A more extensive schematic notation, as well as a VHDL-like textual hardware description language for adiabatic circuits, and related design tools specialized for adiabatic design, including circuit synthesis, simulation, and validation tools are also expected to be completed based on the principles described herein. These would facilitate the design of fully-adiabatic circuits, which is presently somewhat cumbersome when constrained to using traditional languages, design tools, and notations.

The invention is expected to have a wide range of applications. Products obtainable from the invention include ultra-low-power (microwatt scale) digital processing components (microprocessors, DSPs, FPGAs, ASICs) for embedded systems based on currently available CMOS technologies. It is expected that extremely power-efficient high-performance processors for tightly-coupled parallel applications (e.g. typical supercomputer applications) in which energy dissipation is a major limiting factor on performance will begin to utilize the invention. In addition, high-performance, energy-efficient computers using nanometer-scale switching elements operating near the limits of physical information encoding efficiency, regardless of whether these logic elements are electronic or use other physical domains for information processing (such as electromechanical, mechanical, optical, optoelectronic, spintronic, chemical, or fluidic), as long as adiabatic transitions within the given domain can be driven by the trapezoidal voltage signal generated by these resonators can also benefit from the invention. Higher-level products requiring any of the above components, such as desktop/laptop/server computers, supercomputers, PDAs, wireless communication devices, smart tags, autonomous wireless sensors, implanted medical devices, and nano-robots can also benefit from the invention.

### EXAMPLES

The present invention is further illustrated by the following specific examples, which should not be construed as limiting the scope or content of the invention in any way.

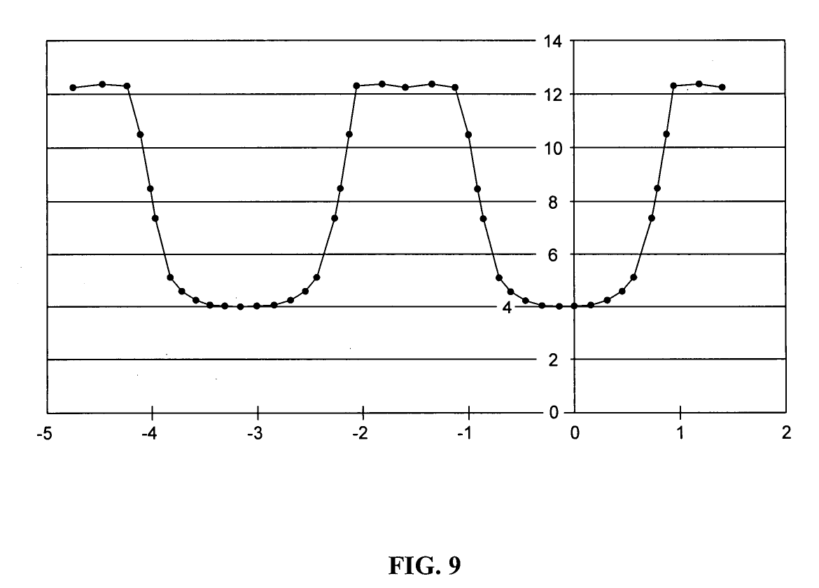

A finite-element MEMS simulator CoventorWare® (Coventor, Inc., Cary, N.C.) was used to design the non-uniformly shaped sensing comb fingers to generate the desired output waveforms. One exemplary waveform obtained from the simulation is shown in FIG. 9. The flat top of the trapezoidal signal is realized by custom tuning the shape of the sense comb fingers, such as the comb fingers having rectangular-shaped end portions that are enlarged relative to the remaining portions, as illustrated above. The nearly flat bottom of the waveform is due to the very small change of the fringing capacitance when the movable fingers are far from the stationary fingers.

As illustrated above, when the MEMS waveform generator 300 is at rest, the movable and stationary sensing comb fingers are separated by 3 μm. When the resonator moves to the maximum amplitude position, the minimum gap dₛ between the (movable and stationary) sense comb fingers is as small as 0.1 μm. Gaps less than 0.1 μm are also achievable, but the maximum applied voltage will then need to be decreased due to air breakdown. Some design parameters are shown in Table 1 below. A 20 fF sense capacitance variation was achieved.

TABLE 1
Some key parameters of a prototype resonator at 0.5 MHz resonant
frequency.

| | | | |
|---|---|---|---|
| Thickness: | 2 μm | Bias voltage | 10 V |
| | | V_{b}: | |
| Min. gap size: | 0.1 μm | DC drive | 10 V |
| | | voltage \|V_{c} − V_{b}\|: | |
| Min. feature size: | 0.5 μm | AC drive | 0.2 V |
| | | voltage ν_{ac}: | |
| # of actuation fingers | 20 | Area A: | 107 μm × 36 μm |
| Nₐ: | | | |
| # of sensing fingers | 106 | Capacitance | 20 fF |
| Nₛ: | | variation: | |
| Quality factor Q: | 5000 (est.) | Effective | 46 |
| | | quality factor | |
| | | Q_{eff}: | |
| Vibration amplitude X: | 4 μm | Area efficiency | 3.23 × 10⁻⁴ J/m² |
| | | α_{E} | |

The sensing capacitance variation is only 0.2 fF per comb finger. However, it should be feasible to increase the structure thickness by a factor of 20 using an available Deep Reactive Ion Etching (DRIE) process which can yield a figure closer to 4 fF per comb finger. Using a bias voltage of 10 V and 10 comb fingers, this means each comb finger could drive a load equivalent to about 40 minimum sized devices of about 1 fF load capacitance each, through a voltage swing of ˜1V. The area needed for this many devices is close to the area occupied by the comb finger.

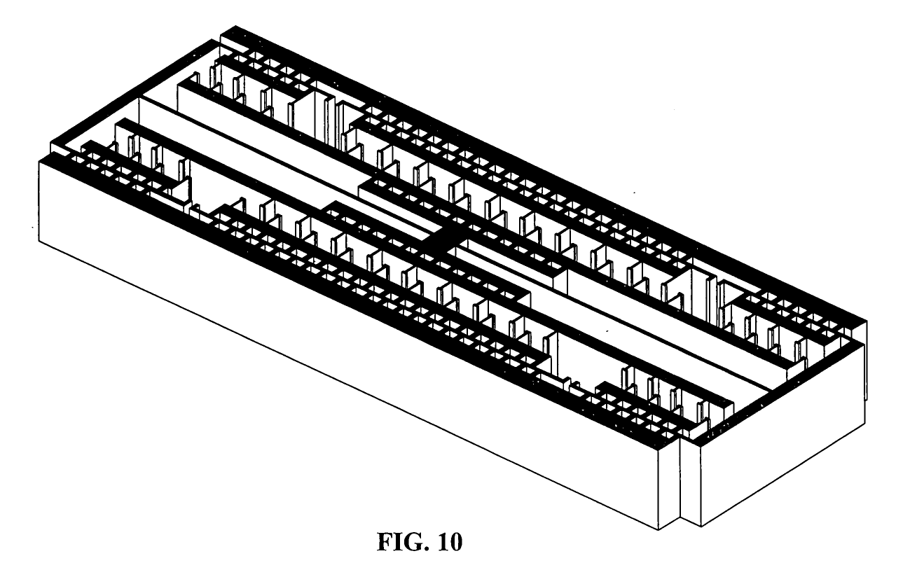

A prototype design with somewhat lower resonant frequency using the Taiwan Semiconductor Manufacturing Company (TSMC) 0.35 μm CMOS process was taped out and has been fabricated. The 3D model of the resonator design is shown in FIG. 10. This is a resonator prototype with much larger size which can generate the trapezoidal waveform at much lower frequency (around 100 kHz). The total area is 300 μm by 160 μm. In this design, the effective quality factor and area efficiency are not optimized. The parameters for this resonator are listed in Table 2. The resonant frequency can be scaled up with a smaller resonator.

TABLE 2
Some key parameters of the prototype 100 kHz resonator shown in
FIG. 10.

| | | | |
|---|---|---|---|
| Thickness: | 30 μm | Bias voltage V_{b}: | 10 V |
| Min. gap size: | 0.5 μm | DC drive voltage | 50 V |
| | | \|V_{c} − V_{b}\|: | |
| Min. feature size: | 2.5 μm | AC drive voltage | 2 V |
| | | ν_{ac}: | |
| # of actuation | 48 | Area A: | 300 μm × 160 μm |
| fingers Nₐ: | | | |
| # of sensing | 24 | Capacitance | 30 fF |
| fingers Nₛ: | | variation: | |
| Quality factor Q: | 5000 (est.) | Effec. Qual. | 0.16 |
| | | factor Q_{eff}: | |
| Vibration amplitude | 16 μm | Area eff. α_{E} | 1.1 × 10⁻⁴ J/m² |
| X: | | | |

To optimize the resonator design requires a joint system-level optimization in concert with the logic, in order to select the optimal operating frequency, voltages, and resonator area so as to maximize the overall gain in cost-performance from the adiabatic design. From the resonator point of view, given the limitation of air breakdown voltage, the optimization of Q_{eff} and α_{E} is done by maximizing the sense capacitance variation and minimizing the vibration amplitude and the resonator area. New regions of the design space need to be explored to further improve these parameters.

Simulations based on BSIM3 device models were performed by the inventors of the invention to calculate the maximum operating frequencies for logic in the TSMC 0.18 μm CMOS technology presently used for designing the 2LAL test circuits. Preliminary results show that, at an example ultra-low power level of 7 pW per logic gate, standard CMOS can run at a maximum frequency of only 80 kHz, by operating in a subthreshold regime with V_{dd}=180 mV, while adiabatic CMOS can run at up to 3.9 MHz, at a much higher voltage of 1.7 V, while still satisfying the power constraint. The adiabatic performance boost is thus about 50× and the cost-efficiency boost is about ˜12× in the application scenario used (with 4× overhead).

Although the peak frequency of ˜4 MHz in this scenario is a little higher than achieved with conventional resonator prototypes, further design refinements in a newer MEMS process should be able to easily move the invention well into the MHz frequency range. Once this is done, based on the preliminary analyses performed, it is expected to be able to empirically demonstrate roughly an order-of-magnitude reduction in energy dissipation in our MEMS/2LAL design compared with standard CMOS, when optimized using the design methodology described herein. As MEMS technology pushes down towards the nanoscale, further refinements of these techniques are expected to lead to significant boosts in both performance and cost-performance for particularly power-limited applications in the near-term, and in the long term for most high-performance computations.

As noted above, in certain applications, adiabatics can provide improved results as compared to conventional approaches. With conventional voltage scaling, severe limitations are encountered due to the substantially increased effective resistance (and low on/off ratio) suffered by devices operated in the low-voltage regime. The high effective resistance constrains devices to be operated so slowly that their low on/off ratio severely limits the energy savings that can be achieved, due to the relatively high off-state leakage current, and the substantial resulting standby power consumption. In contrast, the adiabatic approach permits operating energy-efficiently at much higher voltages, at which the effective on-resistance remains small and the on/off ratio remains high, so that leakage is much less of a factor. Moreover, an adiabatic device does not have to be slowed down by as large a factor as a voltage-scaled device in order to achieve a given reduction in power dissipation, due to the quadratic (rather than linear) scaling of power with frequency. The end result is that at a given low level of power dissipation, the adiabatic approach can ultimately offer higher performance than any competing approach in the same process technology.

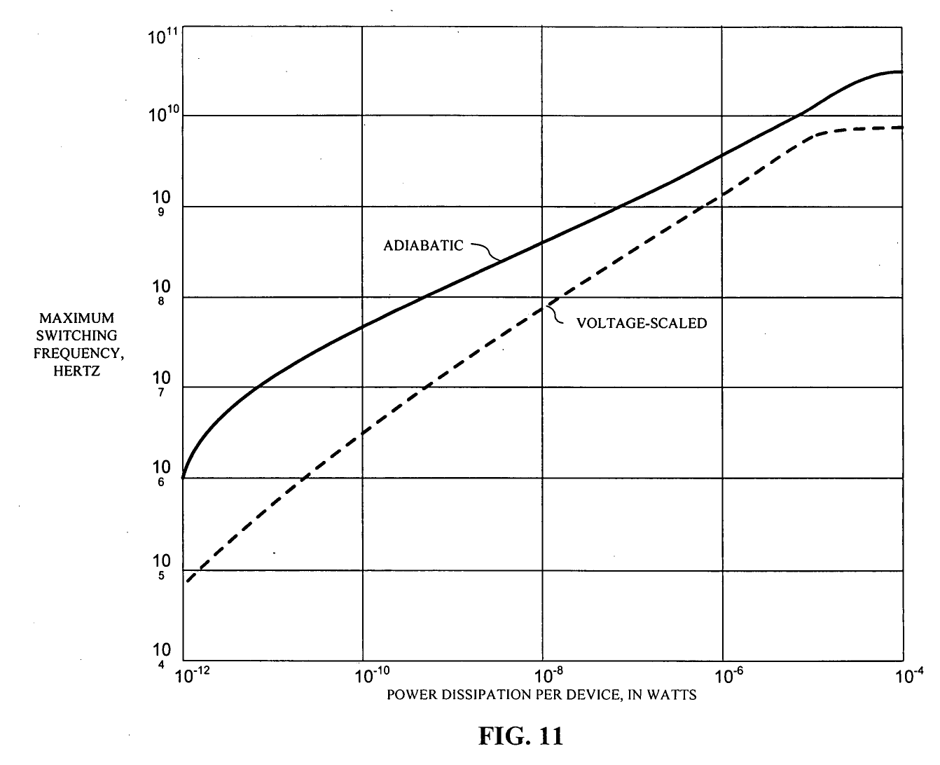

FIG. 11 shows simulation results based on an optimization analysis using a standard device model for the TSMC 0.18 μm process technology confirming the performance advantage in maximum frequency vs. power dissipation provided by adiabatic circuits as compared to a conventional voltage scaled circuit. The upper line in the plot shows the adiabatic circuit while the lower line shows the conventional voltage scaled circuit. At low power levels, the conventional voltage-scaling approach suffers from reduced drive current (increased effective channel resistance) at low supply levels, which limits the maximum operating frequency to a level that is at most roughly proportional to power. In contrast, the adiabatically switched device can continue to be operated at the recommended operating voltage of the technology (1.8 V), while performance falls off more slowly, roughly with only the square root of the power drop. Near the left of the FIG. 11, it can be seen that by the time an ultra-low-power level of 6.3×10⁻¹² W (roughly 10 pW) per device is reached, near the lower limit set by leakage power, the adiabatic device is running at ˜50× the frequency of a conventional device (12.7 MHz vs. 260 kHz) in this particular example.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

1. A MEMS waveform generator, comprising:
a plurality of capacitive sensors, each capacitive sensor comprising a movable sensor portion and a corresponding fixed sensor portion, the movable and fixed sensor portions each having a plurality of electrically conductive features, at least one of the electrically conductive features having at least one predetermined non-uniform portion;
an actuator for receiving a time-varying input signal and causing the movable sensor portion to move relative to the corresponding fixed sensor portion in response thereto.

2. The MEMS waveform generator of claim 1, wherein the actuator is an electrostatic actuator microstructure comprising a movable actuator portion and a fixed actuator portion, the movable actuator portion and the fixed actuator portion each having a plurality of electrically conductive features, the fixed actuator portion for receiving the time varying input signal and oscillating a position of the movable actuator portion in response thereto.

3. The MEMS waveform generator of claim 2, wherein the MEMS waveform generator is disposed on a substrate and the time-varying input signal generates an electrostatic force, and further comprising a flexural beam connected to the substrate and to the movable actuator portion for oscillating the movable actuator relative to the fixed actuator portion in response to the electrostatic force.

4. The MEMS waveform generator of claim 3, wherein the substrate comprises single-crystal silicon.

5. The MEMS waveform generator of claim 1, wherein at least a portion of the plurality of features are formed from single-crystal silicon.

6. The MEMS waveform generator of claim 1, wherein the time-varying input signal comprises a sinusoidal excitation signal, and wherein the MEMS waveform generator generates a waveform comprising multiple frequency components in response to the sinusoidal excitation signal when it is applied to the actuator.

7. The MEMS waveform generator of claim 1, wherein the MEMS waveform generator provides a substantially trapezoidal output signal in response to the time-varying input signal.

8. The MEMS waveform generator of claim 7, wherein the time-varying input signal is a sinusoidal signal.

9. The MEMS waveform generator of claim 1, wherein the at least one non-uniformly shaped portion of at least one feature comprises an expanded end portion that is enlarged relative to other portions of the at least one feature.

10. The MEMS waveform generator of claim 1, wherein the at least one non-uniformly shaped portion of at least one feature comprises a rectangular end portion.

11. The MEMS waveform generator of claim 1, wherein the at least one non-uniformly shaped portion of at least one feature comprises a triangular end portion.

12. The MEMS waveform generator of claim 1, wherein the at least one non-uniformly shaped portion of at least one feature comprises a trapezoidal portion.

13. The MEMS waveform generator of claim 1, wherein the at least one non-uniformly shaped portion of at least one feature comprises a curved surface portion.

14. An adiabatic circuit comprising:
at least one circuit load; and
a MEMS waveform generator for driving the at least one circuit load, the MEMS waveform generator including
a plurality of capacitive sensors, each capacitive sensor comprising a movable sensor portion and a corresponding fixed sensor portion, the movable and fixed sensor portions each having a plurality of electrically conductive features, at least one of the electrically conductive features having at least one predetermined non-uniform portion, and
an actuator for receiving a time-varying input signal and causing the movable sensor portion to move relative to the corresponding fixed sensor portion in response thereto.

15. The adiabatic circuit of claim 14, wherein the time-varying input signal comprises a sinusoidal excitation signal, and wherein the MEMS waveform generator generates a waveform comprising multiple frequency components in response to the sinusoidal excitation signal when it is applied to the actuator.

16. The adiabatic circuit of claim 14, wherein the MEMS waveform generator provides a substantially trapezoidal output signal in response to the time-varying input signal.

17. The MEMS waveform generator of claim 16, wherein the time-varying input signal is a sinusoidal signal.

18. The adiabatic circuit of claim 14, wherein the adiabatic circuit comprises a logic circuit, and wherein the at least one circuit load comprises a logic gate.

19. The adiabatic circuit of claim 18, wherein the logic circuit is a two-level adiabatic logic circuit.

20. A method of generating a waveform for driving a circuit, the method comprising the steps of:
providing a time-varying signal; and
moving a plurality of movable electrically conductive features relative a corresponding plurality of fixed electrically conductive features in response to the time-varying signal, at least one of the plurality of electrically conductive features having at least one predetermined non-uniform portion.
